(19) United States
(12) Patent Application Publication
(10) Pub. No.: US 2026/0297379 A1
(43) Pub. Date: Oct. 1, 2026

(54) CMP POLISHING LIQUID AND POLISHING METHOD

(71) Applicant: Resonac Corporation, Tokyo (JP)

(72) Inventors: Masahiro KANNO, Tokyo (JP); Hiroshi NAKAGAWA, Tokyo (JP); Hiroshi ONO, Tokyo (JP); Shintaro FUKUDA, Tokyo (JP); Taira ONUMA, Tokyo (JP); Tetsuya OGAWA, Tokyo (JP)

(73) Assignee: Resonac Corporation, Tokyo (JP)

(21) Appl. No.: 19/477,587

(22) PCT Filed: Dec. 11, 2024
(86) PCT No.: PCT/JP2024/043874

§ 371 Date: Oct. 22, 2025

(30) Foreign Application Priority Data
Dec. 14, 2023 (WO) PCT/JP2023/044933

(51) Int. Cl. C09G 1/02; H10P 52/40

(52) U.S. Cl. CPC C09G 1/02; H10P 52/402

(57) ABSTRACT

A CMP polishing liquid for polishing a member to be polished containing a carbon material, the CMP polishing liquid containing abrasive grains, iron ions, and an organic acid. A polishing method including a step of polishing a member to be polished containing a carbon material using the CMP polishing liquid. A method for manufacturing a semiconductor device, including obtaining a semiconductor device using a member to be polished that has been polished by the polishing method.

### TECHNICAL FIELD

The present disclosure relates to a CMP polishing liquid, a polishing method, and the like.

### BACKGROUND ART

In recent years, electronic devices have become smaller and more sophisticated, and accordingly, demands for higher integration and higher performance of semiconductor integrated circuits (LSIs) have become extremely strict. One of the technologies for achieving higher integration and higher performance of semiconductor integrated circuits (LSIs) is CMP (Chemical Mechanical Polishing) technology. CMP technology is a technique for polishing the surface of a substrate by pressing the substrate against a polishing pad while supplying a polishing liquid between the surface of the substrate and the polishing pad, thereby making the surface of a semiconductor wafer flat and smooth, and is a particularly important technology in the planarization of layers formed on the wafer.

In semiconductor integrated circuits (LSIs) aiming for higher integration and higher functionality, the use of carbon materials (for example, polyimide resins) having excellent properties such as electrical insulation, heat resistance, and mechanical strength is increasing. Carbon materials are used as insulating layers between different metal layers and between wirings, but because of their high hardness and chemical resistance, it is required that they can be efficiently removed by CMP. In response to such demands, Patent Literature 1 describes a polishing composition containing at least one type of abrasive grains having a modified Mohs hardness of 13 or more, as a polishing liquid capable of polishing a polyimide film in a short time, maintaining high flatness, and suppressing the occurrence of polishing scratches.

### CITATION LIST

### Patent Literature

Patent Literature 1: Japanese National Phase PCT Patent Publication No. 2010-135472

### SUMMARY OF INVENTION

### Technical Problem

When polishing a carbon material, it may be required to simultaneously polish not only the carbon material but also a metal material. Therefore, a CMP polishing liquid used for polishing a carbon material may be required to polish not only the carbon material but also the metal material at a high polishing rate.

Therefore, an aspect of the present disclosure aims to provide a CMP polishing liquid capable of polishing a carbon material and a metal material at an excellent polishing rate. Another aspect of the present disclosure aims to provide a polishing method using such a CMP polishing liquid.

### Solution to Problem

The present disclosure includes, for example, the following [1] to [18].

[1] A CMP polishing liquid for polishing a member to be polished containing a carbon material, the CMP polishing liquid containing abrasive grains, iron ions, and an organic acid.

[2] The CMP polishing liquid according to [1], wherein the abrasive grains include particles having an old Mohs hardness of less than 8.

[3] The CMP polishing liquid according to [1] or [2], wherein the abrasive grains include silica particles.

[4] The CMP polishing liquid according to any one of [1] to [3], wherein the content of the iron ions is from 0.001 to 0.2 mass %.

[5] The CMP polishing liquid according to any one of [1] to [4], wherein a mass ratio of the content of the abrasive grains to the content of the iron ions is from 50 to 500.

[6] The CMP polishing liquid according to any one of [1] to [5], further containing an oxidizing agent.

[7] The CMP polishing liquid according to [6], wherein the oxidizing agent includes a peroxide.

[8] The CMP polishing liquid according to any one of [1] to [7], further containing an organic acid component.

[9] The CMP polishing liquid according to [8], wherein the organic acid component includes an amino acid component.

[10] The CMP polishing liquid according to [8] or [9], wherein the content of the organic acid component is from 0.1 to 5 mass %.

[11] The CMP polishing liquid according to any one of [1] to [10], further containing an organic solvent.

[12] The CMP polishing liquid according to [11], wherein the organic solvent includes 3-methoxy-3-methyl-1-butanol.

[13] The CMP polishing liquid according to any one of [1] to [12], wherein the pH is from 1.0 to 7.0.

[14] The CMP polishing liquid according to any one of [1] to [13], wherein the carbon material includes a polyimide resin.

[15] The CMP polishing liquid according to any one of [1] to [14], wherein the member to be polished further contains a metal material.

[16] The CMP polishing liquid according to [15], wherein the metal material includes at least one selected from the group consisting of copper, copper alloy, copper oxide, and copper alloy oxide.

[17] A polishing method including a step of polishing a member to be polished containing a carbon material using the CMP polishing liquid according to any one of [1] to [16].

[18] A method for manufacturing a semiconductor device, including obtaining a semiconductor device using a member to be polished that has been polished by the polishing method according to [17].

### Advantageous Effects of Invention

According to an aspect of the present disclosure, it is possible to provide a CMP polishing liquid capable of polishing a carbon material and a metal material at an excellent polishing rate. According to another aspect of the present disclosure, it is possible to provide a polishing method using such a CMP polishing liquid.

### DESCRIPTION OF EMBODIMENTS

Hereinafter, embodiments of the present disclosure will be described.

In the present specification, a numerical range indicated using “to” indicates a range including the numerical values described before and after “to” as the minimum value and the maximum value, respectively. “A or more” in a numerical range means a range of A and more than A. “A or less” in a numerical range means a range of A and less than A. In the numerical ranges described in stages in the present specification, an upper limit value or a lower limit value of a numerical range at one stage can be arbitrarily combined with an upper limit value or a lower limit value of a numerical range at another stage. In the numerical ranges described in the present specification, the upper limit value or the lower limit value of the numerical range may be replaced with a value shown in the Examples. “A or B” means that it may include either one of A and B, or may include both. Materials exemplified in the present specification may be used alone or in combination of two or more, unless otherwise specified. The content of each component in a composition means the total amount of a plurality of substances corresponding to the component present in the composition, unless otherwise specified. The term “step” includes not only an independent step but also a case where the intended action of the step is achieved even if the step cannot be clearly distinguished from other steps.

The CMP polishing liquid according to the present embodiment (hereinafter, also simply referred to as “polishing liquid”) is a polishing liquid for polishing a carbon material (a polishing liquid for a carbon material), and can be used for polishing a surface to be polished that includes a carbon material. The carbon material is a carbon-containing material that includes carbon atoms. As the carbon material, a material in which carbon atoms are ⅓ or more based on all atoms constituting the carbon material (the content of carbon atoms is 33 atm % or more based on the total amount of atoms constituting the carbon material) can be used. Examples of the carbon material include resin materials such as a polyimide resin, an epoxy resin, an acrylic resin (a polymer having a structural unit derived from a monomer having a (meth)acryloyl group), a polybenzoxazole resin, and a phenol resin; and amorphous carbon (diamond-like carbon (DLC)). The carbon material may include at least one selected from the group consisting of a polyimide resin, an epoxy resin, an acrylic resin, a polybenzoxazole resin, a phenol resin, and amorphous carbon. The carbon material can have a carbon-carbon bond. The carbon material may be a photosensitive resin or a non-photosensitive resin (a resin having no photosensitivity).

A polyimide resin has excellent electrical insulating properties and can be used as an insulating layer between different metal layers and between wirings. Examples of a method for forming a film of the polyimide resin include a method of forming a thin film from a polyimide solution by a spin coating method, a dip coating method, a spray coating method, or the like, and forming a polyimide resin film by heating and/or light irradiation.

The polishing liquid according to the present embodiment can be used for polishing a surface to be polished that includes a metal material. Examples of the metal material include metals such as copper, nickel, gold, silver, tin, zinc, platinum, bismuth, indium, and antimony, alloys of these metals, oxides of these metals, and oxides of alloys of these metals. The polishing liquid according to the present embodiment may be used for polishing a surface to be polished that includes at least one selected from the group consisting of copper, copper alloy, copper oxide, and copper alloy oxide.

The polishing liquid according to the present embodiment contains abrasive grains, iron ions, and an organic acid. According to the polishing liquid of the present embodiment, a carbon material and a metal material can be polished at an excellent polishing rate. According to the polishing liquid of the present embodiment, a polishing rate of the carbon material of, for example, 100 nm/min or more can be obtained in the evaluation described in the Examples below. Further, according to the polishing liquid of the present embodiment, a polishing rate of the metal material of, for example, 30 nm/min or more can be obtained in the evaluation described in the Examples below.

The reason why the effect of being able to polish a carbon material and a metal material at an excellent polishing rate is obtained is not clear, but the following reasons are exemplified. However, the reason why the above-described effect is obtained is not limited to the following content. That is, iron ions and an organic acid modify the carbon material, whereby molecular chains (such as carbon-carbon bonds) of the carbon material are cleaved and the mechanical strength of the carbon material is reduced. It is inferred that this allows the carbon material to be polished at an excellent polishing rate. Furthermore, the organic acid modifies the metal material, thereby reducing the mechanical strength of the metal material. Then, it is inferred that the metal material can be polished at an excellent polishing rate by the abrasive grains.

The polishing liquid according to the present embodiment can be used for polishing in, for example, a wiring formation step and the like of a semiconductor device. The polishing liquid according to the present embodiment can be suitably used for polishing a carbon material used as a constituent material of a hard mask, as well as for polishing an interlayer insulating film using a carbon material, and the like. The polishing liquid according to the present embodiment can also be suitably used for polishing a metal material used as a constituent material of a metal wiring, and the like.

Examples of the abrasive grains include silica particles, cerium oxide (ceria) particles, cerium hydroxide particles, aluminum oxide (alumina) particles, silicon nitride particles, zirconium oxide (zirconia: yttria-doped zirconia particles, etc.) particles, titanium oxide (titania) particles, yttrium oxide (yttria) particles, silicon carbide particles, diamond particles, polymer particles, and the like. From the viewpoint of easily polishing a carbon material and a metal material at an excellent polishing rate, and from the viewpoint that defects such as scratches are less likely to occur on the polished surface of the object to be polished and the flatness of the surface to be polished is likely to be improved, the abrasive grains may include particles having an old Mohs hardness of less than 8, may include particles having an old Mohs hardness of 5 or more and less than 8, may include particles having an old Mohs hardness of 5 to 7, may include particles having an old Mohs hardness of 6 to 7, and may include at least one selected from the group consisting of silica particles and cerium oxide particles. The old Mohs hardness means a value measured using a Mohs hardness tester on a bulk body having the same composition as the abrasive grains.

The polishing liquid according to the present embodiment contains abrasive grains. When silica particles are included as the abrasive grains, examples of the silica particles include colloidal silica, amorphous silica, crystalline silica, fused silica, spherical silica, synthetic silica, hollow silica, and the like. When the polishing liquid contains abrasive grains, from the viewpoint of easily polishing a carbon material and a metal material at an excellent polishing rate, and from the viewpoint that defects such as scratches are less likely to occur on the polished surface of the object to be polished and the flatness of the surface to be polished is likely to be improved, the polishing liquid may include colloidal silica as the abrasive grains.

The average particle size of the abrasive grains may be 10 nm or more, 15 nm or more, 20 nm or more, 25 nm or more, 30 nm or more, 35 nm or more, 40 nm or more, 45 nm or more, 50 nm or more, 55 nm or more, or 60 nm or more, from the viewpoint that the physical polishing ability per abrasive grain is easily sufficiently secured, which makes it easy to polish a carbon material and a metal material at an excellent polishing rate. The average particle size of the abrasive grains may be 1000 nm or less, 800 nm or less, 600 nm or less, 400 nm or less, 300 nm or less, 200 nm or less, 190 nm or less, 180 nm or less, 150 nm or less, 120 nm or less, 100 nm or less, 80 nm or less, or 70 nm or less, from the viewpoint that the number of abrasive grains per unit area in contact with the surface to be polished is easily sufficiently secured, which makes it easy to polish a carbon material and a metal material at an excellent polishing rate. From these viewpoints, the average particle size of the abrasive grains may be 10 to 1000 nm, 10 to 600 nm, 10 to 200 nm, 10 to 100 nm, 10 to 80 nm, 15 to 190 nm, 20 to 180 nm, 30 to 100 nm, 30 to 200 nm, 30 to 80 nm, 50 to 200 nm, 50 to 100 nm, or 50 to 80 nm.

The “average particle size” is the secondary particle size of the abrasive grains and can be obtained by measuring the particle size of the abrasive grains in the polishing liquid or the particle size of the abrasive grains before being blended into the polishing liquid. The average particle size can be measured by a light diffraction scattering particle size distribution analyzer, and may be measured by preparing a sample in which the abrasive grains are dispersed in water. For example, using a COULTER N4SD manufactured by COULTER Electronics, measurement can be performed under the conditions of measurement temperature: 20° C., solvent refractive index: 1.333 (water), particle refractive index: Unknown (setting), solvent viscosity: 1.005 cp (water), Run Time: 200 seconds, laser incident angle: 90°, and Intensity (scattering intensity, corresponding to turbidity): 5E+04 to 4E+05. If the Intensity is higher than 4E+05, measurement can be performed after diluting with water. Since colloidal particles are usually obtained in a state of being dispersed in water, they can also be measured by appropriately diluting them to fall within the above-mentioned range of scattering intensity.

The content of silica particles in the abrasive grains may be 50 mass % or more, more than 50 mass %, 60 mass % or more, 70 mass % or more, 80 mass % or more, 90 mass % or more, 95 mass % or more, 98 mass % or more, or 99 mass % or more, based on the total mass of the abrasive grains (the entire abrasive grains included in the polishing liquid), from the viewpoint of easily polishing a carbon material and a metal material at an excellent polishing rate. The abrasive grains may be in an embodiment consisting of silica particles (substantially 100 mass % of the abrasive grains included in the polishing liquid are silica particles).

The polishing liquid according to the present embodiment may not contain aluminum oxide (alumina) particles, and the abrasive grains may not include aluminum oxide (alumina). The content of aluminum oxide (alumina) particles may be 0.01 mass % or less, less than 0.01 mass %, 0.001 mass % or less, or 0.0001 mass % or less, based on the total mass of the polishing liquid.

The polishing liquid according to the present embodiment may not contain zirconia particles, and the abrasive grains may not include zirconia. The content of zirconia particles may be 0.01 mass % or less, less than 0.01 mass %, 0.001 mass % or less, or 0.0001 mass % or less, based on the total mass of the polishing liquid.

The content of the abrasive grains may be in the following range based on the total mass of the polishing liquid. The content of the abrasive grains may be 20 mass % or less, 15 mass % or less, 10 mass % or less, 8 mass % or less, 5 mass % or less, 3 mass % or less, or 1 mass % or less, based on the total mass of the polishing liquid, from the viewpoint that the amount of abrasive grains per unit area of the surface to be polished decreases, making it easier for iron ions to preferentially contact the surface to be polished, promoting the modification of the carbon material, thereby making it easy to polish the carbon material at an excellent polishing rate, and from the viewpoint of making it easy to suppress the occurrence of scratches. The content of the abrasive grains may be 0.01 mass % or more, 0.05 mass % or more, 0.1 mass % or more, 0.5 mass % or more, 1 mass % or more, 3 mass % or more, or 5 mass % or more, from the viewpoint of easily polishing a metal material at an excellent polishing rate.

The mass ratio of the content of the abrasive grains to the content of the iron ions (content of abrasive grains/content of iron ions) may be in the following range. The mass ratio may be 10000 or less, 8000 or less, 6000 or less, 5000 or less, 4000 or less, 3000 or less, 2500 or less, 2000 or less, 1500 or less, 1000 or less, 800 or less, 700 or less, 600 or less, or 500 or less, from the viewpoint that the amount of abrasive grains per unit area of the surface to be polished decreases, making it easier for iron ions to preferentially contact the surface to be polished, promoting the modification of the carbon material, thereby making it easy to polish the carbon material at an excellent polishing rate, and from the viewpoint of making it easy to suppress the occurrence of scratches. The mass ratio may be 1 or more, 5 or more, 10 or more, 30 or more, 40 or more, 50 or more, 60 or more, 70 or more, 80 or more, 90 or more, or 100 or more, from the viewpoint of easily polishing a metal material at an excellent polishing rate. The mass ratio may be 400 or less, 300 or less, 250 or less, 200 or less, 150 or less, or 100 or less, and may be 150 or more, 200 or more, 300 or more, or 400 or more. From these viewpoints, the mass ratio may be 1 to 10000, 1 to 5000, 1 to 1000, 1 to 500, 5 to 10000, 5 to 5000, 5 to 1000, 5 to 500, 10 to 10000, 5 to 5000, 10 to 1000, 10 to 500, 50 to 10000, 50 to 5000, 50 to 1000, or 50 to 500.

The polishing liquid according to the present embodiment contains iron ions. The iron ions may include at least one selected from the group consisting of Fe²⁺ and Fe³⁺, from the viewpoint of easily polishing a carbon material at an excellent polishing rate.

By obtaining a polishing liquid using an iron ion-supplying agent, a polishing liquid containing iron ions can be obtained. The polishing liquid according to the present embodiment may contain an iron ion-supplying agent. The iron ion-supplying agent supplies iron ions into the polishing liquid.

Examples of the iron ion-supplying agent include salts of iron ions, hydrates of said salts, and the like. The salt of iron ions may include at least one selected from the group consisting of an inorganic salt and an organic salt. Examples of the inorganic salt include iron nitrate, iron sulfate, iron boride, iron chloride, iron bromide, iron iodide, iron phosphate, iron fluoride, and the like. Examples of the organic salt include iron(III) formate, iron(II) formate, iron acetate, iron propionate, iron oxalate, iron malonate, iron succinate, iron malate, iron glutarate, iron tartrate, iron lactate, iron citrate, and the like. The salt of iron ions (inorganic salt, organic salt, etc.) may include a ligand such as ammonium, water, or the like.

In a polishing liquid containing an iron ion-supplying agent, the iron ion-supplying agent may exist in a state of being dissociated into iron ions and an anion derived from the iron ion-supplying agent. The polishing liquid according to the present embodiment may contain at least one selected from the group consisting of nitrate ions and acetate ions, from the viewpoint of easily polishing a carbon material at an excellent polishing rate. The polishing liquid according to the present embodiment may contain at least one selected from the group consisting of iron nitrate, a hydrate of iron nitrate, and iron acetate, from the viewpoints of easily polishing a carbon material at an excellent polishing rate, relatively little contamination of a polishing apparatus, a substrate, etc., and being inexpensive and easily available.

The content of the iron ions may be in the following range based on the total mass of the polishing liquid. The content of the iron ions may be 0.0001 mass % or more, 0.0005 mass % or more, 0.001 mass % or more, 0.0012 mass % or more, 0.0014 mass % or more, 0.002 mass % or more, 0.003 mass % or more, 0.004 mass % or more, 0.005 mass % or more, 0.0055 mass % or more, 0.006 mass % or more, 0.007 mass % or more, 0.008 mass % or more, 0.009 mass % or more, 0.01 mass % or more, more than 0.01 mass %, 0.011 mass % or more, 0.02 mass % or more, 0.03 mass % or more, 0.04 mass % or more, 0.05 mass % or more, 0.06 mass % or more, 0.07 mass % or more, 0.08 mass % or more, 0.09 mass % or more, 0.1 mass % or more, more than 0.1 mass %, or 0.11 mass % or more, from the viewpoint of easily polishing a carbon material at an excellent polishing rate. The content of the iron ions may be 10 mass % or less, 8 mass % or less, 6 mass % or less, 5 mass % or less, 4 mass % or less, 3 mass % or less, 2 mass % or less, 1 mass % or less, less than 1 mass %, 0.9 mass % or less, 0.8 mass % or less, 0.7 mass % or less, 0.6 mass % or less, 0.5 mass % or less, 0.4 mass % or less, 0.3 mass % or less, 0.2 mass % or less, 0.15 mass % or less, 0.12 mass % or less, 0.1 mass % or less, less than 0.1 mass %, 0.09 mass % or less, 0.08 mass % or less, 0.07 mass % or less, 0.06 mass % or less, 0.05 mass % or less, 0.04 mass % or less, 0.03 mass % or less, 0.02 mass % or less, 0.015 mass % or less, 0.012 mass % or less, 0.01 mass % or less, or less than 0.01 mass %. From these viewpoints, the content of the iron ions may be 0.0001 to 10 mass %, 0.0001 to 5 mass %, 0,0001 to 1 mass %, 0.0005 to 0.5 mass %, 0.001 to 0.2 mass %, or 0.0014 to 0.12 mass %. The content of the iron ion-supplying agent may be adjusted so that the content of iron ions in the polishing liquid falls within the above-mentioned respective ranges. When converting the content of iron ions (unit: mass %) to a content (unit: mM), a specific gravity of 1 may be adopted for the polishing liquid. When the content of iron ions is 0.001 to 10 mass %, the content of iron ions can be converted to 0.018 to 179 mM.

The polishing liquid according to the present embodiment contains an organic acid component. Examples of the organic acid component include an organic acid, a salt thereof (for example, an alkali metal salt such as a sodium salt; an alkaline earth metal salt such as a calcium salt), and the like. By using the organic acid component, the carbon material and the metal material are modified, and the carbon material and the metal material can be polished at an excellent polishing rate. Although the effect of improving the polishing rate of the carbon material is not obtained when the organic acid component is used in the absence of iron ions, the polishing rate of the carbon material can be improved when the organic acid component is used in the presence of iron ions.

The polishing liquid according to the present embodiment can contain an oxidizing agent such as hydrogen peroxide, as described later. In such a polishing liquid, the decomposition of the oxidizing agent may proceed due to the interaction between the iron ions and the oxidizing agent (hydrogen peroxide, etc.), and the storage stability of the polishing liquid may be impaired. On the other hand, such decomposition of the oxidizing agent can be suppressed by using an organic acid component.

The reason why the above-described effect is obtained by the organic acid component is not clear, but it is presumed that the organic acid component dissociates in the polishing liquid, and the dissociated organic acid component chelates the iron ions, thereby suppressing the decomposition of the oxidizing agent by the iron ions. However, the reason why the above-described effect is obtained is not limited to this content. “Dissociation” means that a cation (for example, a proton (H+)) is released from at least one acid group (for example, a carboxy group (—COOH)) that the organic acid component has in the polishing liquid, and the acid group exists in the state of an anionic group (for example, —COO—).

The organic acid component may include an organic acid component that does not have a carbon-carbon unsaturated bond, from the viewpoint of making it easier to keep the oxidizing agent more stable and to stabilize the polishing rates of the carbon material and the metal material. The reason why the stability of the oxidizing agent is improved when the organic acid component does not have a carbon-carbon unsaturated bond is not clear, but it is presumed that one reason is that since the reactivity of the carbon-carbon unsaturated bond is relatively high, alteration due to a reaction between the oxidizing agent and the organic acid component in the polishing liquid is less likely to occur when the organic acid component does not have a carbon-carbon unsaturated bond. However, the reason why the above-described effect is obtained is not limited to this content.

Examples of the organic acid include saturated fatty acids such as formic acid, acetic acid, and propionic acid; dicarboxylic acids such as malonic acid, succinic acid, glutaric acid, and adipic acid; hydroxy acids such as malic acid and citric acid; and amino acids described later. The organic acid may or may not contain malic acid.

The polishing liquid may contain at least one amino acid component (excluding a compound containing iron ions or a compound corresponding to an oxidizing agent) selected from the group consisting of an amino acid and an amino acid derivative, from the viewpoint of easily polishing a carbon material and a metal material at an excellent polishing rate. An amino acid is a compound having both an amino group and a carboxyl group as functional groups. Examples of the amino acid derivative include esters of amino acids, salts of amino acids, peptides, and the like. The amino acid component can be used as a pH adjuster for adjusting the pH of the polishing liquid.

Examples of the amino acid component include glycine, α-alanine, β-alanine (also known as 3-aminopropanoic acid), 2-aminobutyric acid, norvaline, valine, leucine, norleucine, isoleucine, alloisoleucine, phenylalanine, proline, sarcosine, ornithine, lysine, serine, threonine, allothreonine, homoserine, tyrosine, 3,5-diiodo-tyrosine, β-(3,4-dihydroxyphenyl)-alanine, thyroxine, 4-hydroxy-proline, cysteine, methionine, ethionine, lanthionine, cystathionine, cystine, cysteic acid, aspartic acid, glutamic acid, S-(carboxymethyl)-cysteine, 4-aminobutyric acid, asparagine, glutamine, azaserine, arginine, canavanine, citrulline, 8-hydroxy-lysine, creatine, kynurenine, histidine, 1-methyl-histidine, 3-methyl-histidine, ergothioneine, tryptophan, glycylglycine, glycylglycylglycine, vasopressin, oxytocin, cassinin, eledoisin, glucagon, secretin, proopiomelanocortin, enkephalin, prodynorphin, and the like. The amino acid component may include at least one selected from the group consisting of glycine and β-alanine, from the viewpoint of easily polishing a carbon material and a metal material at an excellent polishing rate.

The content of glycine in the organic acid or amino acid may be 50 mass % or more, more than 50 mass %, 60 mass % or more, 70 mass % or more, 80 mass % or more, 90 mass % or more, 95 mass % or more, 98 mass % or more, or 99 mass % or more, based on the total mass of the organic acid (the entire organic acid included in the polishing liquid) or the total mass of the amino acid (the entire amino acid included in the polishing liquid), from the viewpoint of easily polishing a carbon material and a metal material at an excellent polishing rate. The organic acid or amino acid may be in an embodiment consisting of glycine (substantially 100 mass % of the organic acid or amino acid included in the polishing liquid is glycine).

The content of the organic acid component may be in the following range based on the total mass of the polishing liquid, from the viewpoint of making it easy to stabilize the polishing rates of the carbon material and the metal material. The content of the organic acid component may be 0.01 mass % or more, 0.05 mass % or more, 0.1 mass % or more, 0.2 mass % or more, 0.3 mass % or more, 0.5 mass % or more, 1 mass % or more, 1.5 mass % or more, 2 mass % or more, 2.5 mass % or more, or 3 mass % or more. The content of the organic acid component may be 10 mass % or less, 5 mass % or less, 3 mass % or less, 1 mass % or less, 0.8 mass % or less, 0.5 mass % or less, or 0.3 mass % or less. From these viewpoints, the content of the organic acid component may be 0.01 to 10 mass %, 0.01 to 5 mass %, 0.01 to 3 mass %, 0.05 to 10 mass %, 0.05 to 5 mass %, 0.05 to 3 mass %, 0.1 to 10 mass %, 0.1 to 5 mass %, or 0.1 to 3 mass %. The content of the amino acid component may be within the above-mentioned range.

The mass ratio of the content of the organic acid component to the content of the abrasive grains (content of organic acid component/content of abrasive grains) may be in the following range, from the viewpoint of easily polishing a carbon material and a metal material at an excellent polishing rate. The mass ratio may be 0.01 or more, 0.05 or more, 0.1 or more, or 0.3 or more. The mass ratio may be 30 or less, 20 or less, 10 or less, 5 or less, or 3 or less. From these viewpoints, the mass ratio may be 0.01 to 30, 0.05 to 20, 0.1 to 10, or 0.3 to 5. The mass ratio of the content of the amino acid component to the content of the abrasive grains (content of amino acid component/content of abrasive grains) may be within the above-mentioned range.

The mass ratio of the content of the organic acid component to the content of the iron ions (content of organic acid/content of iron ions) may be in the following range, from the viewpoint of easily polishing a carbon material and a metal material at an excellent polishing rate. The mass ratio may be 0.1 or more, 0.5 or more, 1 or more, 2 or more, 10 or more, 50 or more, 100 or more, 150 or more, 200 or more, or 250 or more. The mass ratio may be 3000 or less, 2500 or less, 2200 or less, 2000 or less, 1500 or less, 1000 or less, 800 or less, 600 or less, 500 or less, 400 or less, 350 or less, 250 or less, 200 or less, 150 or less, 100 or less, 50 or less, or 30 or less. From these viewpoints, the mass ratio may be 0.1 to 3000, 0.1 to 2000, 0.1 to 500, 0.1 to 300, 0.1 to 100, 0.1 to 30, 1 to 3000, 1 to 2000, 1 to 500, 1 to 300, 1 to 100, 1 to 30, 2 to 3000, 2 to 2000, 2 to 500, 2 to 300, 2 to 100, or 2 to 30. The mass ratio of the content of the amino acid component to the content of the iron ions (content of amino acid/content of iron ions) may be within the above-mentioned range.

The polishing liquid according to the present embodiment may contain an oxidizing agent (an oxidizing agent for the carbon material; excluding iron ions or a compound corresponding to a compound containing iron ions). By using an oxidizing agent, the carbon material and the metal material are further modified, and the polishing rates of the carbon material and the metal material are likely to be improved. Although the effect of improving the polishing rate of the carbon material is not obtained when the oxidizing agent is used in the absence of iron ions, the polishing rate of the carbon material can be improved when the oxidizing agent is used in the presence of iron ions.

Examples of the oxidizing agent include hydrogen peroxide, nitric acid, potassium periodate, hypochlorous acid, ozone water, and the like. When the substrate to be polished is a silicon substrate including elements for an integrated circuit, the oxidizing agent may include an oxidizing agent that does not contain a non-volatile component, and may include hydrogen peroxide, from the viewpoint of avoiding contamination by alkali metals, alkaline earth metals, halides, and the like. The oxidizing agent may include a peroxide, and may include hydrogen peroxide, from the viewpoint of easily polishing a carbon material and a metal material at an excellent polishing rate. As the oxidizing agent, a compound having a redox potential weaker than that of iron ions can be used.

The content of the oxidizing agent may be in the following range based on the total mass of the polishing liquid. The content of the oxidizing agent may be 0.1 mass % or more, 0.5 mass % or more, 1 mass % or more, 1.5 mass % or more, 1.7 mass % or more, 2 mass % or more, 2.5 mass % or more, 3 mass % or more, 3.5 mass % or more, or 4 mass % or more, from the viewpoint of easily polishing a carbon material and a metal material at an excellent polishing rate. The content of the oxidizing agent may be 20 mass % or less, 15 mass % or less, 10 mass % or less, 8 mass % or less, 6 mass % or less, 5 mass % or less, 4.5 mass % or less, or 4 mass % or less. From these viewpoints, the content of the oxidizing agent may be 0.1 to 20 mass %, 0.1 to 10 mass %, 0.1 to 5 mass %, 1 to 20 mass %, 1 to 10 mass %, 1 to 5 mass %, 2 to 20 mass %, 2 to 10 mass %, 2 to 5 mass %, 3 to 10 mass %, or 3 to 5 mass %.

The mass ratio of the content of the oxidizing agent to the content of the abrasive grains (content of oxidizing agent/content of abrasive grains) may be in the following range, from the viewpoint of easily polishing a carbon material and a metal material at an excellent polishing rate. The mass ratio may be 0.01 or more, 0.05 or more, 0.1 or more, 0.5 or more, or 0.8 or more. The mass ratio may be 30 or less, 20 or less, 10 or less, 5 or less, or 4 or less. From these viewpoints, the mass ratio may be 0.01 to 30, 0.05 to 20, 0.1 to 10, or 0.5 to 5.

The mass ratio of the content of the oxidizing agent to the content of the iron ions (content of oxidizing agent/content of iron ions) may be in the following range. The mass ratio may be 10 or more, 50 or more, 100 or more, 150 or more, 200 or more, 250 or more, 300 or more, or 350 or more, from the viewpoint of easily polishing a carbon material and a metal material at an excellent polishing rate. The mass ratio may be 3000 or less, 2500 or less, 2000 or less, 1500 or less, 1000 or less, 800 or less, 600 or less, 500 or less, 450 or less, 400 or less, or 370 or less, from the viewpoint of easily polishing a carbon material at an excellent polishing rate. From these viewpoints, the mass ratio may be 10 to 3000, 10 to 2000, 10 to 500, 100 to 3000, 100 to 2000, 100 to 500, 200 to 3000, 200 to 2000, 200 to 500, 300 to 3000, 300 to 2000, or 300 to 500.

The polishing liquid according to the present embodiment may contain an organic solvent (excluding compounds containing iron ions, oxidizing agents, or compounds corresponding to the organic acid component). By using an organic solvent, the polishing rate of a hydrophobic carbon material (for example, a low-dielectric-constant carbon material) may be likely to be improved. In addition, by using an organic solvent, it is easy to suppress the decomposition of the oxidizing agent (for example, hydrogen peroxide), and thus it is easy to polish a carbon material and a metal material at an excellent polishing rate.

As the organic solvent, a solvent that is arbitrarily miscible with water can be used. Examples of the organic solvent include carbonate esters such as ethylene carbonate, propylene carbonate, dimethyl carbonate, diethyl carbonate, and methyl ethyl carbonate; lactone compounds such as butyrolactone and propiolactone; glycol compounds such as ethylene glycol, propylene glycol, diethylene glycol, dipropylene glycol, triethylene glycol, and tripropylene glycol; as derivatives of glycol compounds, glycol monoethers (for example, glycol monoalkyl ethers) such as ethylene glycol monomethyl ether, propylene glycol monomethyl ether, diethylene glycol monomethyl ether, dipropylene glycol monomethyl ether, triethylene glycol monomethyl ether, tripropylene glycol monomethyl ether, ethylene glycol monoethyl ether, propylene glycol monoethyl ether, diethylene glycol monoethyl ether, dipropylene glycol monoethyl ether, triethylene glycol monoethyl ether, tripropylene glycol monoethyl ether, ethylene glycol monopropyl ether, propylene glycol monopropyl ether, diethylene glycol monopropyl ether, dipropylene glycol monopropyl ether, triethylene glycol monopropyl ether, tripropylene glycol monopropyl ether, ethylene glycol monobutyl ether, propylene glycol monobutyl ether, diethylene glycol monobutyl ether, dipropylene glycol monobutyl ether, triethylene glycol monobutyl ether, and tripropylene glycol monobutyl ether; glycol diethers such as ethylene glycol dimethyl ether, propylene glycol dimethyl ether, diethylene glycol dimethyl ether, dipropylene glycol dimethyl ether, triethylene glycol dimethyl ether, tripropylene glycol dimethyl ether, ethylene glycol diethyl ether, propylene glycol diethyl ether, diethylene glycol diethyl ether, dipropylene glycol diethyl ether, triethylene glycol diethyl ether, tripropylene glycol diethyl ether, ethylene glycol dipropyl ether, propylene glycol dipropyl ether, diethylene glycol dipropyl ether, dipropylene glycol dipropyl ether, triethylene glycol dipropyl ether, tripropylene glycol dipropyl ether, ethylene glycol dibutyl ether, propylene glycol dibutyl ether, diethylene glycol dibutyl ether, dipropylene glycol dibutyl ether, triethylene glycol dibutyl ether, and tripropylene glycol dibutyl ether; ether compounds such as tetrahydrofuran, dioxane, dimethoxyethane, polyethylene oxide, ethylene glycol monomethyl ether acetate, diethylene glycol monoethyl ether acetate, and propylene glycol monomethyl ether acetate; alcohols such as methanol, ethanol, propanol, n-butanol, n-pentanol, n-hexanol, and isopropanol; alkoxy alcohols such as 2-methoxyethanol, 2-ethoxyethanol, 2-(2-methoxy)ethoxyethanol, 2-(2-butoxyethoxy)ethanol, 2-propoxyethanol, 2-butoxyethanol, 3-methoxy-3-methyl-1-butanol, 2-(methoxymethoxy)ethanol, 2-isopropoxyethanol, 2-butoxyethanol, 2-isopentyloxyethanol, 1-propoxy-2-propanol, 3-methoxy-3-methyl-1-butanol, 3-methoxy-1-butanol, 3-methoxy-3-methylbutanol, 1-methoxy-2-butanol, and glycol monoethers; ketones such as acetone and methyl ethyl ketone; phenol; dimethylformamide; N-methylpyrrolidone; ethyl acetate; ethyl lactate; sulfolane, and the like.

The organic solvent may include an alkoxy alcohol, and may include 3-methoxy-3-methyl-1-butanol, from the viewpoint that the polishing rate of a hydrophobic carbon material is likely to be improved.

The content of the organic solvent may be in the following range based on the total mass of the polishing liquid. The content of the organic solvent may be 0.1 mass % or more, 0.2 mass % or more, 0.5 mass % or more, 1 mass % or more, 2 mass % or more, 2.5 mass % or more, or 3 mass % or more, from the viewpoint that sufficient wettability of the polishing liquid with respect to the substrate is easily obtained and the polishing rate of a hydrophobic carbon material is likely to be improved. The content of the organic solvent may be 95 mass % or less, 50 mass % or less, 30 mass % or less, 10 mass % or less, 8 mass % or less, 6 mass % or less, 5 mass % or less, 4 mass % or less, or 3 mass % or less, from the viewpoint that the polishing rate of a hydrophobic carbon material is likely to be improved, and from the viewpoint of making it easy to reduce the possibility of ignition. From these viewpoints, the content of the organic solvent may be 0.1 to 95 mass %, 0.1 to 50 mass %, 0.1 to 5 mass %, 1 to 95 mass %, 1 to 50 mass %, 1 to 5 mass %, 2 to 95 mass %, 2 to 50 mass %, or 2 to 5 mass %.

The polishing liquid according to the present embodiment may contain additives other than the above-described components. Examples of such additives include a pH adjuster, a polymeric material, and the like.

The polishing liquid according to the present embodiment may contain a base component as a pH adjuster. Examples of the base component include sodium hydroxide, ammonia (for example, ammonia water), potassium hydroxide, calcium hydroxide, and the like.

The content of the base component may be in the following range based on the total mass of the polishing liquid. The content of the base component may be more than 0 mass %, 0.00001 mass % or more, 0.00005 mass % or more, 0.0001 mass % or more, 0.0005 mass % or more, 0.001 mass % or more, or 0.005 mass % or more. The content of the base component may be 10 mass % or less, 5 mass % or less, 1 mass % or less, 0.5 mass % or less, 0.1 mass % or less, or 0.05 mass % or less.

The polishing liquid according to the present embodiment may contain water. The content of water in the polishing liquid may be the remainder obtained by subtracting the contents of the other components from the total amount of the polishing liquid. The content of water may be 50 mass % or more, 70 mass % or more, 80 mass % or more, or 90 mass % or more, based on the total mass of the polishing liquid. The polishing liquid according to the present embodiment may be stored as a stock solution for a polishing liquid having a lower water content than at the time of polishing. In this case, the polishing liquid can be obtained by diluting the stock solution for a polishing liquid with water at the time of polishing.

The pH of the polishing liquid according to the present embodiment may be less than 9.0, 8.5 or less, 8.0 or less, 7.5 or less, 7.0 or less, less than 7.0, 6.5 or less, 6.0 or less, less than 6.0, 5.5 or less, 5.2 or less, 5.0 or less, less than 5.0, 4.8 or less, 4.6 or less, 4.5 or less, 4.4 or less, or 4.3 or less, from the viewpoint of easily polishing a carbon material and a metal material at an excellent polishing rate. The pH of the polishing liquid may be 1.0 or more, 1.2 or more, 1.5 or more, 2.0 or more, more than 2.0, 2.2 or more, 2.4 or more, 2.6 or more, 2.8 or more, 3.0 or more, more than 3.0, 3.2 or more, 3.4 or more, 3.6 or more, 3.8 or more, 4.0 or more, more than 4.0, 4.1 or more, or 4.2 or more, from the viewpoint of easily polishing a carbon material and a metal material at an excellent polishing rate. From these viewpoints, the pH of the polishing liquid may be 1.0 or more and less than 9.0, 1.0 to 8.0, 1.0 to 7.0, 1.0 to 6.0, 1.0 to 5.0, 1.0 to 4.5, 2.0 or more and less than 9.0, 2.0 to 8.0, 2.0 to 7.0, 2.0 to 6.0, 2.0 to 5.0, 2.0 to 4.5, 3.0 or more and less than 9.0, 3.0 to 8.0, 3.0 to 7.0, 3.0 to 6.0, 3.0 to 5.0, or 3.0 to 4.5. The pH of the polishing liquid is defined as the pH at a liquid temperature of 25° C.

The pH of the polishing liquid according to the present embodiment can be measured with a pH meter (for example, trade name: Model (F-51) manufactured by HORIBA, Ltd.). For example, after performing a three-point calibration of the pH meter using a phthalate pH standard solution (pH: 4.01), a neutral phosphate pH standard solution (pH: 6.86), and a borate pH standard solution (pH: 9.18) as calibration solutions, the electrode of the pH meter is placed in the polishing liquid, and the value after it has stabilized for 2 minutes or more is measured. At this time, the liquid temperature of the calibration solutions and the polishing liquid is set to 25° C.

The polishing method according to the present embodiment includes a polishing step of polishing a carbon material using the polishing liquid according to the present embodiment. In the polishing step, a surface to be polished including a carbon material may be polished, and a surface to be polished of a material to be polished including a carbon material may be polished, using the polishing liquid according to the present embodiment. In the polishing step, a surface to be polished of a hard mask including a carbon material may be polished using the polishing liquid according to the present embodiment. In the polishing step, a surface to be polished including a metal material may be polished, and a surface to be polished of a material to be polished including a metal material may be polished, using the polishing liquid according to the present embodiment. The polishing liquid used in the polishing step may be a polishing liquid obtained by diluting a stock solution for a polishing liquid with water. The surface to be polished may have a layer containing at least one selected from the group consisting of a carbon material and a metal material.

In the polishing step, for example, the surface to be polished of a substrate is pressed against a polishing cloth of a polishing platen, and while a predetermined pressure is applied to the substrate from the surface opposite to the surface to be polished of the substrate (the back surface of the substrate), the polishing liquid according to the present embodiment is supplied between the surface to be polished of the substrate and the polishing cloth, and the substrate is moved relative to the polishing platen, whereby the surface to be polished can be polished.

As the polishing apparatus, for example, when polishing with a polishing cloth, a general polishing apparatus having a holder capable of holding a substrate to be polished, and a polishing platen connected to a motor or the like whose rotation speed can be changed and to which a polishing cloth can be attached, can be used. As the polishing cloth, a general non-woven fabric, foamed polyurethane, porous fluororesin, or the like can be used, and there is no particular limitation.

There are no limitations on the polishing conditions, but the rotation speed of the polishing platen may be a low rotation of 200 rpm (rpm=min⁻¹) or less so that the substrate does not fly out. The pressure for pressing the substrate having the surface to be polished (such as a semiconductor substrate) against the polishing cloth may be 1 to 100 kPa, or 5 to 50 kPa, from the viewpoint of easily satisfying the in-plane uniformity of the polishing rate and the flatness of the pattern. During polishing, the polishing liquid can be continuously supplied to the polishing cloth by a pump or the like. There is no limitation on this supply amount, but the surface of the polishing cloth may be constantly covered with the polishing liquid.

In order to perform polishing (such as CMP) with the surface state of the polishing cloth always being the same, a conditioning step of the polishing cloth may be performed before polishing. For example, the polishing cloth can be conditioned with a liquid containing at least water using a dresser with diamond particles attached. Subsequently, after performing the polishing method according to the present embodiment, a substrate cleaning step may be further performed. The substrate after polishing may be thoroughly washed in running water, and then water droplets adhering to the substrate may be removed using a spin dryer or the like, followed by drying. In addition, after performing a known cleaning method (for example, a method of removing adhered substances on the substrate by pressing a rotating polyurethane brush against the substrate with a constant pressure while flowing a commercially available cleaning liquid over the substrate surface), the substrate may be dried.

The method for manufacturing a part according to the present embodiment includes a part manufacturing step of obtaining a part using a member to be polished (a member to be polished containing a carbon material and/or a metal material) that has been polished by the polishing method according to the present embodiment. The member to be polished (a member to be polished containing a carbon material) that has been polished by the polishing method according to the present embodiment may be used as a hard mask. The part according to the present embodiment is a part obtained by the method for manufacturing a part according to the present embodiment. The part according to the present embodiment is not particularly limited, but may be an electronic component (for example, a semiconductor component such as a semiconductor package), may be a wafer (for example, a semiconductor wafer), and may be a chip (for example, a semiconductor chip). As one aspect of the method for manufacturing a part according to the present embodiment, in the method for manufacturing an electronic component according to the present embodiment, an electronic component is obtained using a member to be polished that has been polished by the polishing method according to the present embodiment. As one aspect of the method for manufacturing a part according to the present embodiment, in the method for manufacturing a semiconductor component according to the present embodiment, a semiconductor component (for example, a semiconductor package) is obtained using a member to be polished that has been polished by the polishing method according to the present embodiment. The method for manufacturing a part according to the present embodiment may include, before the part manufacturing step, a polishing step of polishing the member to be polished by the polishing method according to the present embodiment.

The method for manufacturing a part according to the present embodiment may include, as one aspect of the part manufacturing step, a singulation step of singulating a member to be polished (a member to be polished containing a carbon material and/or a metal material) that has been polished by the polishing method according to the present embodiment. The singulation step may be, for example, a step of obtaining chips (for example, semiconductor chips) by dicing a wafer (for example, a semiconductor wafer) that has been polished by the polishing method according to the present embodiment. As one aspect of the method for manufacturing a part according to the present embodiment, the method for manufacturing an electronic component according to the present embodiment may include a step of obtaining an electronic component (for example, a semiconductor component) by singulating a member to be polished that has been polished by the polishing method according to the present embodiment. As one aspect of the method for manufacturing a part according to the present embodiment, the method for manufacturing a semiconductor component according to the present embodiment may include a step of obtaining a semiconductor component (for example, a semiconductor package) by singulating a member to be polished that has been polished by the polishing method according to the present embodiment.

The method for manufacturing a part according to the present embodiment may include, as one aspect of the part manufacturing step, a connection step of connecting (for example, electrically connecting) a member to be polished (a member to be polished containing a carbon material and/or a metal material) that has been polished by the polishing method according to the present embodiment to another member to be connected. The member to be connected, which is connected to the member to be polished that has been polished by the polishing method according to the present embodiment, is not particularly limited, and may be a member to be polished that has been polished by the polishing method according to the present embodiment, or may be a member to be connected that is different from the member to be polished that has been polished by the polishing method according to the present embodiment. In the connection step, the member to be polished and the member to be connected may be directly connected (connected in a state where the member to be polished and the member to be connected are in contact), or the member to be polished and the member to be connected may be connected via another member (such as a conductive member). The connection step can be performed before the singulation step, after the singulation step, or before and after the singulation step.

The connection step may be a step of connecting the surface to be polished of the member to be polished that has been polished by the polishing method according to the present embodiment and the member to be connected, and may be a step of connecting the connection surface of the member to be polished that has been polished by the polishing method according to the present embodiment and the connection surface of the member to be connected. The connection surface of the member to be polished may be the surface to be polished that has been polished by the polishing method according to the present embodiment. By the connection step, a connected body including the member to be polished and the member to be connected can be obtained. In the connection step, when the connection surface of the member to be polished has a metal part, the member to be connected may be brought into contact with the metal part. In the connection step, when the connection surface of the member to be polished has a metal part and the connection surface of the member to be connected has a metal part, the metal parts may be brought into contact with each other. The metal part may include copper.

A device according to the present embodiment (for example, an electronic device such as a semiconductor device) includes at least one selected from the group consisting of a member to be polished (a member to be polished containing a carbon material and/or a metal material) that has been polished by the polishing method according to the present embodiment, and a part according to the present embodiment.

### EXAMPLES

Hereinafter, the present disclosure will be described in more detail with reference to Examples, but the present disclosure is not limited to these Examples as long as it does not depart from the technical idea of the present disclosure.

### <Preparation of CMP Polishing Liquid>

### Example 1

Iron (III) nitrate nonahydrate and abrasive grains (colloidal silica, trade name: PL-10H, average particle size: 179 nm, old Mohs hardness: 6 to 7) were mixed in deionized water. Then, glycine, a 30 mass % aqueous solution of hydrogen peroxide, and MMB were added to obtain a CMP polishing liquid. Based on the total mass of the CMP polishing liquid, the content of the abrasive grains (content of silica as solid content) was 1 mass %, the content of iron(III) nitrate nonahydrate was 0.08 mass % (content of iron ions: 0.011 mass %), the content of glycine was 3.00 mass %, the content of hydrogen peroxide (content of hydrogen peroxide itself) was 4.00 mass %, and the content of MMB was 3.00 mass %.

### Example 2

A CMP polishing liquid was obtained in the same manner as in Example 1, except that the content of the abrasive grains was changed to 5 mass %.

### Example 3

A CMP polishing liquid was obtained in the same manner as in Example 1, except that the content of iron(III) nitrate nonahydrate was changed to 0.04 mass % (content of iron ions: 0.0055 mass %).

### Example 4

A CMP polishing liquid was obtained in the same manner as in Example 1, except that the content of iron(III) nitrate nonahydrate was changed to 0.12 mass % (content of iron ions: 0.017 mass %).

### Example 5

A CMP polishing liquid was obtained in the same manner as in Example 1, except that the content of glycine was changed to 0.30 mass %.

### Example 6

A CMP polishing liquid was obtained in the same manner as in Example 1, except that the content of glycine was changed to 0.60 mass %.

### Example 7

A CMP polishing liquid was obtained in the same manner as in Example 1, except that the content of glycine was changed to 1.50 mass %.

### Example 8

A CMP polishing liquid was obtained in the same manner as in Example 1, except that glycine was changed to β-alanine, and the content of β-alanine was 0.30 mass %.

### Example 9

A CMP polishing liquid was obtained in the same manner as in Example 1, except that glycine was changed to β-alanine, and the content of β-alanine was 4.00 mass %.

### Comparative Example 1

A CMP polishing liquid was obtained in the same manner as in Example 1, except that iron(III) nitrate nonahydrate was changed to a 0.1 mol/L aqueous solution of zinc acetate, and the content of zinc acetate (content of zinc acetate itself) was 0.04 mass % (content of zinc ions: 0.013 mass %).

### Comparative Example 2

A CMP polishing liquid was obtained in the same manner as in Example 1, except that abrasive grains were not included and hydrogen peroxide was not included.

### <Measurement of Average Particle Size of Abrasive Grains>

As a result of measuring the average particle size of the abrasive grains in the above-described CMP polishing liquids using a COULTER N4SD manufactured by COULTER Electronics, there was no change in the average particle size of the abrasive grains before and after the preparation of the polishing liquid in all Examples.

<Measurement of pH>

The pH of the above-described CMP polishing liquids was measured using a trade name “Model (F-51)” manufactured by HORIBA, Ltd. Specifically, after performing a three-point calibration of the pH meter using a phthalate pH standard solution (pH: 4.01), a neutral phosphate pH standard solution (pH: 6.86), and a borate pH standard solution (pH: 9.18) as calibration solutions, the electrode of the pH meter was placed in the CMP polishing liquid, and the value after it had stabilized for 2 minutes or more was measured. The liquid temperature of the calibration solutions and the CMP polishing liquids was 25° C. The results are shown in Table 1.

### <Measurement of Polishing Rate>

As an evaluation test wafer, a 12-inch diameter substrate having a 10 μm thick polyimide resin layer (HD7000 series, manufactured by HD Microsystems) on a silicon substrate was prepared. In addition, as an evaluation test wafer, a 12-inch diameter substrate having a 1.5 μm thick copper layer on a silicon substrate was prepared. Using the above-described CMP polishing liquids, the polyimide resin layer and the copper layer were respectively polished (CMP) under the following polishing conditions. The difference in the thickness of the polyimide resin layer before and after polishing was measured using an optical film thickness meter (F54-UV, manufactured by Filmetrics, Inc.), the difference in the thickness of the copper layer before and after polishing was measured using a metal film thickness meter (WS-3000, manufactured by Napson Corporation), and the polishing rates of the polyimide resin and copper were calculated based on the difference in the thickness of each of the polyimide resin layer and the copper layer and the polishing time. The results are shown in Tables 1 and 2.

### [Polishing Conditions]

Polishing apparatus: trade name “Reflexion LK”, manufactured by Applied Materials, Inc.

Polishing pad: IK4250H (manufactured by DuPont)

Polishing pressure: 4 psi

Platen rotation speed: 87 rpm

Head rotation speed: 93 rpm

CMP polishing liquid supply rate: 300 mL/min

Polishing time: 1 minute

TABLE 1

| | | | | | | | | | | | Compar- | Compar- |
|---|---|---|---|---|---|---|---|---|---|---|---|---|
| | | | | | | | | | | | ative | ative |
| | | Exam- | Exam- | Exam- | Exam- | Exam- | Exam- | Exam- | Exam- | Exam- | Example | Example |
| | | ple 1 | ple 2 | ple 3 | ple 4 | ple 5 | ple 6 | ple 7 | ple 8 | ple 9 | 1 | 2 |
| Abrasive | PL-10H | 1 | 5 | 1 | 1 | 1 | 1 | 1 | 1 | 1 | 1 | — |
| grains | KE-W30 | — | — | — | — | — | — | — | — | — | — | — |
| (mass %) | IX-3-SH- | — | — | — | — | — | — | — | — | — | — | — |
| | W50 | | | | | | | | | | | |
| | ST-AK- | — | — | — | — | — | — | — | — | — | — | — |
| | YL-A | | | | | | | | | | | |
| Iron ions | Derived | 0.011 | 0.011 | 0.0055 | 0.017 | 0.011 | 0.011 | 0.011 | 0.011 | 0.011 | — | 0.011 |
| (mass %) | from iron | | | | | | | | | | | |
| | nitrate | | | | | | | | | | | |
| | Derived | — | — | — | — | — | — | — | — | — | — | — |
| | from iron | | | | | | | | | | | |
| | acetate | | | | | | | | | | | |
| Metal ions | Derived | — | — | — | — | — | — | — | — | — | 0.013 | — |
| other than | from zinc | | | | | | | | | | | |
| iron ions | acetate | | | | | | | | | | | |
| (mass %) | | | | | | | | | | | | |
| Organic | Glycine | 3.00 | 3.00 | 3.00 | 3.00 | 0.30 | 0.60 | 1.50 | — | — | 3.00 | 3.00 |
| acid | β-alanine | — | — | — | — | — | — | — | 0.30 | 4.00 | — | — |
| component | | | | | | | | | | | | |
| (mass %) | | | | | | | | | | | | |
| Oxidizing | Hydrogen | 4.00 | 4.00 | 4.00 | 4.00 | 4.00 | 4.00 | 4.00 | 4.00 | 4.00 | 4.00 | — |
| agent | peroxide | | | | | | | | | | | |
| (mass %) | | | | | | | | | | | | |
| Organic | MMB | 3.00 | 3.00 | 3.00 | 3.00 | 3.00 | 3.00 | 3.00 | 3.00 | 3.00 | 3.00 | 3.00 |
| solvent | | | | | | | | | | | | |
| (mass %) | | | | | | | | | | | | |
| pH | | 4.29 | 4.28 | 4.64 | 4.10 | 3.19 | 3.52 | 3.95 | 4.26 | 5.54 | — | 4.31 |
| Polishing | Polyimide | 353 | 270 | 235 | 463 | 381 | 373 | 382 | 231 | 349 | 5 | 342 |
| rate | resin | | | | | | | | | | | |
| (nm/min) | Copper | 1745 | 1967 | 1899 | 1916 | 311 | 554 | 1158 | 67 | 185 | — | 17 |

1. A CMP polishing liquid for polishing a member to be polished comprising a carbon material, comprising abrasive grains, iron ions, and an organic acid.

2. The CMP polishing liquid according to claim 1, wherein the abrasive grains comprise particles having an old Mohs hardness of less than 8.

3. The CMP polishing liquid according to claim 1, wherein the abrasive grains comprise silica particles.

4. The CMP polishing liquid according to claim 1, wherein the content of the iron ions is from 0.001 to 0.2 mass %.

5. The CMP polishing liquid according to claim 1, wherein a mass ratio of the content of the abrasive grains to the content of the iron ions is from 50 to 500.

6. The CMP polishing liquid according to claim 1, further comprising an oxidizing agent.

7. The CMP polishing liquid according to claim 6, wherein the oxidizing agent comprises a peroxide.

8. The CMP polishing liquid according to claim 1, further comprising an organic acid component.

9. The CMP polishing liquid according to claim 8, wherein the organic acid component comprises an amino acid component.

10. The CMP polishing liquid according to claim 8, wherein the content of the organic acid component is from 0.1 to 5 mass %.

11. The CMP polishing liquid according to claim 1, further comprising an organic solvent.

12. The CMP polishing liquid according to claim 11, wherein the organic solvent comprises 3-methoxy-3-methyl-1-butanol.

13. The CMP polishing liquid according to claim 1, wherein the pH is from 1.0 to 7.0.

14. The CMP polishing liquid according to claim 1, wherein the carbon material comprises a polyimide resin.

15. The CMP polishing liquid according to claim 1, wherein the member to be polished further comprises a metal material.

16. The CMP polishing liquid according to claim 15, wherein the metal material comprises at least one selected from the group consisting of copper, copper alloy, copper oxide, and copper alloy oxide.

17. A polishing method comprising a step of polishing a member to be polished comprising a carbon material using the CMP polishing liquid according to claim 1.

18. A method for manufacturing a semiconductor device, comprising obtaining a semiconductor device using a member to be polished that has been polished by the polishing method according to claim 17.
